(19) United States
(12) Patent Application Publication
(10) Pub. No.: US 2008/0285040 A1
(43) Pub. Date: Nov. 20, 2008

(54) Electrical Detection of Plasmon Resonances

(76) Inventors: John T. Fourkas, Bethesda, MD (US); Daniel Lim, Arlington, MA (US); Christopher Lafratta, Revere, MA (US); Michael J. Naughton, Norwood, MA (US)

Correspondence Address: FISH & RICHARDSON PC, P.O. BOX 1022, MINNEAPOLIS, MN, 55440-1022, US

(21) Appl. No.: 11/816,252

(22) PCT Filed: Feb. 27, 2006
(86) PCT No.: PCT/US2006/007091

§ 371 Date: Mar. 13, 2008

Related U.S. Application Data
(60) Provisional application No. 60/657,053, filed on Feb. 28, 2005.
(60) Provisional application No. 60/660,922, filed on Mar. 11, 2005.

(51) Int. Cl. G01N 21/62; G01R 27/02

(52) U.S. Cl. 356/445; 324/702

(57) ABSTRACT

A method includes detecting a plasmon resonance in a material based on a change in at least one electrical property of the material. For example, the material can be a sensor portion of an electrical circuit, wherein the method can further include: exposing the sensor portion to a test material; optically illuminating the sensor portion when the test material is present, and monitoring the change in the at least one electrical property of the sensor portion in response to the optical illumination. The monitored changed in the at least one electrical property of the sensor portion can provide information about the test material, such as the presence or absence of selected analytes and/or their binding affinities. In another example, the material is a part of a receiver for a plasmonic circuit. An apparatus for carrying out the method is also disclosed.

### CROSS REFERENCE TO RELATED APPLICATIONS

This application claims priority from U.S. Provisional Patent Application No. 60/657,053, filed on Feb. 28, 2005 and U.S. Provisional Patent Application No. 60/660,922, filed on Mar. 11, 2005, the contents of each of which is incorporated herein by reference in its entirety.

### STATEMENT AS TO FEDERALLY SPONSORED RESEARCH

This invention was made with Government support under Grants Nos. ECS-0088438 and ECS-0210497 awarded by the National Science Foundation. The Government has certain rights in this invention.

### BACKGROUND

This invention relates to electrical detection of plasmon resonances, with applications including sensor applications (for example, nanoscale sensor arrays) and waveguide applications.

A plasmon resonance is a collective excitation of charge density. For example, the surface electrons of metals such as gold are loosely bound, and form a plasma. The plasma has natural frequencies at which it oscillates, and these oscillations are an example of a plasmon resonance. The frequencies of such plasmon resonances are highly sensitive to the local environment, and can shift in response to, for example, molecular binding on the metal surface. The plasmon resonance formed by loosely bound electrons on a metal-dielectric interface is commonly referred to as a surface plasmon resonance (“SPR”).

SPR sensors can provide powerful information about the binding of molecules to immobilized binding sites. For gold, the plasmon resonance frequencies are in the visible range of the electromagnetic spectrum, which is particularly useful for sensing applications. In a common SPR sensing scheme, a binding agent is immobilized on (i.e., stuck to) a gold surface and the angle-dependent reflectivity of a monochromatic laser is measured. Binding events cause small spectral shifts in, and attenuation of, the SPR frequency, which lead to changes in refractive index that are detected by changes in the angular dependence of the reflectivity of the surface. To resolve the angle-dependent reflectivity, a laser beam is reflected from the surface over a range of angles and detected by a moving detector or a detector array. It is also possible to measure other properties of the reflected laser beam, such as wavelength-resolved attenuation and polarization rotation to infer additional information about the SPR and its local environment. See, for example, J. Homola et al., “Surface plasmon resonance sensors: review,” Sensors and Actuators B 54 (1999), 3-15.

In addition to sensor applications, plasmon resonances hold promise for waveguide applications. Over the past decade there has been a strong push to integrate optics with electronics on the microscopic scale. Many areas of technology, perhaps most notably communications, stand to benefit from such integration. However, conventional waveguides that are significantly smaller than the wavelength of light are too lossy for most applications. Thus, while the feature sizes for electronic circuits grow ever smaller, conventional photonics has hit a wall in miniaturization.

One approach to the miniaturization of waveguides is to decrease the wavelength of light of a given frequency by decreasing the speed of light. With transparent materials there is only a limited amount that can be done to increase the index of refraction. However, this goal can be attained in non-transparent media in which light can be converted into plasmon modes, allowing for lateral confinement on a scale of roughly 1/20 of the wavelength of light in vacuum.

There have been a number of demonstrations of plasmon waveguiding in recent years. Two basic approaches have been taken. In the first type of approach, individual metal nanorods are used as the waveguiding material. For example, light of an appropriate wavelength can be coupled into a gold or silver nanorod in the near field and then propagate out of the other end, again in the near field. The second approach is to use closely-spaced arrays of individual nanoparticles or nanorods. When free-electron metal nanostructures are placed in close proximity to one another (where close proximity is determined predominantly by the spatial extent of the plasmon evanescent wave), collective behavior is observed. While nanoscale movement and manipulation of plasmon resonances have been demonstrated, generating and detecting such signals typically involve macroscopic optical sources and macroscopic optical detectors, respectively.

### SUMMARY

Among some aspects, the invention features methods and Systems that electrically detect plasmon resonances and changes in their properties in response to, for example, a molecular binding event. The electrical detection is especially useful when the plasmon resonance material is small (for example, nanorods or nanowires), and enables the formation of a densely packed array of nanoscale sensors. For example, because the detection is electrical, it is not necessary to include cumbersome hardware associated with angularly resolved reflection measurements common to conventional SPR sensors. Also, the electrical detection enables the use of reprogrammable bias settings to respective sensors in the sensor array, thereby providing an easily adjustable and independent sensitivity for each sensor in the array. Such sensors have wide-ranging applicability to the detection of biological samples.

The electrical detection also enables transduction of plasmon resonance signals into electrical signals for use in waveguide applications. This simplifies miniaturization of plasmonic devices. For example, it replaces macroscopic optical detectors, which may otherwise be used to detect the plasmon resonance signals.

We now generally summarize different aspects and features of the invention.

In general, in one aspect, the invention features a method including: detecting a plasmon resonance (for example, a surface plasmon resonance) in a material based on a change in at least one electrical property of the material.

Embodiments of the method may include any of the following features.

The material may have a diameter less than about 1 micron, less than about 500 nm, or even less than about 200 nm. The material may have a length less than about 10 microns. The material may include a nanorod or a nanowire. The material may include a first metal that is connected at opposite ends to a second metal different from the first metal.

The at least one electrical property may include any of electrical resistance, impedance, and a frequency dependence of the impedance.

The method may further include monitoring the change in the at least one electrical property of the material. The monitoring may include passing an electrical current through the material and measuring a potential difference across the material as the electrical current is being passed through the material. The electrical current may be a direct current (DC) or an alternating current (AC). If the latter, the monitoring may further include varying a frequency of the alternating current.

The method may further include optically illuminating the material to drive the plasmon resonance in the material. For example, the optical illumination may be include wavelengths in the visible.

The material may be a sensor portion of an electrical circuit, wherein the method further includes: exposing the sensor portion to a test material; optically illuminating the sensor portion when the test material is present, and monitoring the change in the at least one electrical property of the sensor portion in response to the optical illumination. For example, the test material may include a fluid having thiol- or amine-bearing molecules. The sensor portion of the electrical circuit is preferably supported on a substrate that is substantially transparent to the optical illumination.

The optical illumination may be configured to excite a surface plasmon resonance when a selected analyte in the test material binds to the sensor portion.

The optical illumination may be configured to cause the change in the at least one electrical property of the sensor portion when a selected analyte in the test material binds to the sensor portion. For example, the optical illumination may cause the change in the at least one electrical property of the sensor portion by heating the sensor portion when the selected analyte in the test material binds to the sensor portion. The optical illumination may be at least partially absorbed by the sensor portion when the selected analyte in the test material binds to the sensor portion.

The method may further include determining information about the test material based on the monitored change in the at least one electrical property. For example, the information about the test material may include information about a binding affinity of one or more analytes in the test material or information about a presence or absence of a selected analyte in the test material.

Prior to the monitoring, the method may further include illuminating the sensor portion at an intensity sufficient to remove undesired material bound to the sensor portion and thereby expose the sensor portion to a selected analyte in the test material.

Prior to the monitoring, the method may further include applying a bias voltage to the sensor portion to remove undesired material bound to the sensor portion and thereby expose the sensor portion to a selected analyte in the test material.

The method may further include applying a bias voltage to the sensor portion to adjust its affinity for a selected analyte in the test material.

The change in the at least one electrical property of the sensor portion may be monitored in response to varying one or more properties of the illumination, such as polarization, wavelength, or intensity.

The test material may be exposed to multiple sensor portions, each of which is illuminated when the test material is present, and a change in an electrical property of each sensor portion may be monitored in response to the corresponding optical illumination. For example, each sensor portion may be configured to be sensitive to a different analyte in the test material in response to its optical illumination. The physical dimensions of the multiple sensor portions may differ. Furthermore, the properties of the optical illumination (e.g., wavelength, intensity, and polarization) for each sensor portion differ.

The method may further include independently selecting a bias voltage for each sensor portion.

The multiple sensor portions may be formed as an array on a common substrate. For example, the test material may be flowed along a microfluidic channel to expose the multiple sensor portions to the test material.

In another aspect, the material may be a part of a receiver for a plasmonic circuit. For example, the method may further include propagating a plasmon resonance signal along a waveguide and coupling the plasmon resonance signal into the material, wherein the plasmon resonance signal is detected in the material by monitoring the change in at least one electrical property of the material.

In general, in another aspect, the invention features an apparatus including: a material configured to support a plasmon resonance (for example, a surface plasmon resonance); and an electrical sensing circuit coupled to the material, wherein the electrical sensing circuit is configured to monitor a change in at least one electrical property of the material to detect the plasmon resonance. The apparatus may further include a source configured to illuminate the material with electromagnetic radiation to produce the plasmon resonance in the material.

The material may have a diameter less than about 1 micron, less than about 500 nm, or even less than about 200 nm. The material may have a length less than about 10 microns. The material may include a nanorod or a nanowire. The material may include a first metal that is connected at opposite ends to a second metal different from the first metal.

The at least one electrical property may include any of electrical resistance, impedance, and a frequency dependence of the impedance.

The material may include a sensor portion configured to be exposed to a test material and illuminated by the source, and the electrical sensing circuit may be configured to monitor the change in the at least one electrical property in response to the optical illumination when the test material is exposed to the sensor portion. For example, the test material may include a fluid having thiol- or amine-bearing molecules. The sensor portion is preferably supported on a substrate that is substantially transparent to the illumination.

The illumination may be configured to excite a surface plasmon resonance when a selected analyte in the test material binds to the sensor portion. For example, the illumination may include wavelengths in the visible.

The illumination may be configured to cause the change in the at least one electrical property when a selected analyte in the test material binds to the sensor portion. For example, the illumination may cause the change in the at least one electrical property by heating the sensor portion when the selected analyte in the test material binds to the sensor portion. The illumination may be at least partially absorbed by the sensor portion when the selected analyte in the test material binds to the sensor portion.

The apparatus may further include an electronic controller configured to determine information about the test material based on the monitored changed in the at least one electrical property. For example, the information about the test material may include information about a binding affinity of one or more analytes in the test material or information about a presence or absence of a selected analyte in the test material

The source may be configured to selectively illuminate the sensor portion at an intensity sufficient to remove undesired material bound to the sensor portion and thereby expose the sensor portion to a selected analyte in the test material.

The apparatus may further include a power supply configured to selectively apply a bias voltage to the sensor portion to remove undesired material bound to the sensor portion and thereby expose the sensor portion to a selected analyte in the test material.

The apparatus may further include a power supply configured to selectively apply a bias voltage to the sensor portion to adjust its affinity for a selected analyte in the test material.

The apparatus may further include a means for varying an optical property of the illumination, and the electrical sensing circuit may be configured to monitor the change in the at least one electrical property of the sensor portion in response to the variation in the optical property. For example, the optical property may be at least one of polarization, wavelength, and intensity.

The apparatus may include multiple sensor portions each configured to be exposed to the test material, wherein the source is configured to illuminate each sensor portion when exposed to the test material. The apparatus may further include multiple electrical sensing circuits each configured to monitor a change in an electrical property of a corresponding sensor portion in response to the illumination. For example, each sensor portion may be configured to be sensitive to a different analyte in the test material in response to the illumination. The physical dimensions of the multiple sensor portions may differ. The properties of the optical illumination (e.g., wavelength, intensity, and polarization) for each sensor portion may differ.

The apparatus may further including a power supply configured to independently apply a bias voltage for each sensor portion.

The multiple sensor portions may be formed as an array on a common substrate. The apparatus may further include a housing covering the array and defining a microfluidic channel through which the test material is configured to flow to expose the multiple sensor portions to the test material.

In another aspect, the material is a part of a receiver for a plasmonic circuit. For example, the apparatus may further include a plasmonic waveguide configured to propagate a plasmon resonance signal and positioned relative to the receiver to couple the plasmon resonance signal into the material, and wherein the electrical sensing circuit is configured to detect plasmon resonance signal by monitoring the change in at least one electrical property of the material.

As used herein, an “optical” illumination refers to any illumination with electromagnetic radiation (e.g., ultraviolet, visible, near-infrared, etc.); it is not limited to illumination with visible electromagnetic radiation.

Unless otherwise defined, all technical and scientific terms used herein have the same meaning as commonly understood by one of ordinary skill in the art to which this invention belongs. In case of conflict with publications, patent applications, patents, and other references mentioned incorporated herein by reference, the present specification, including definitions, will control.

Other features, objects, and advantages of the invention will be apparent from the following detailed description.

### BRIEF DESCRIPTION OF THE DRAWINGS

FIG. 1 is a schematic diagram of an apparatus for electrically detecting surface plasmon resonances.

FIG. 2 is a schematic diagram of one embodiment of an electrical sensing circuit for use with the apparatus of FIG. 1.

FIG. 3 is a schematic diagram of one embodiment for coupling optical energy into a surface plasmon resonance through attenuated total internal reflection.

FIGS. 4a and 4b are front and side cross-sectional views, respectively, of one embodiment of a surface plasmon resonance sensor array.

FIG. 5 is a schematic diagram of a plasmonic circuit including a plasmonic receiver based on the electrical detection of plasmon resonances.

FIG. 6 is a scanning electron micrograph (SEM) of gold nanorod and associated electrical connections. The inset of FIG. 6 shows a graph voltage versus current measurements of the gold nanorod.

FIG. 7 is a graph of the change in measured voltage as a function of laser power for the gold nanorod of FIG. 6.

FIG. 8 is a graph of the change in measured voltage as a function of linear polarization angle for the gold nanorod of FIG. 6. Like reference numerals in different drawings refer to common elements.

### DETAILED DESCRIPTION

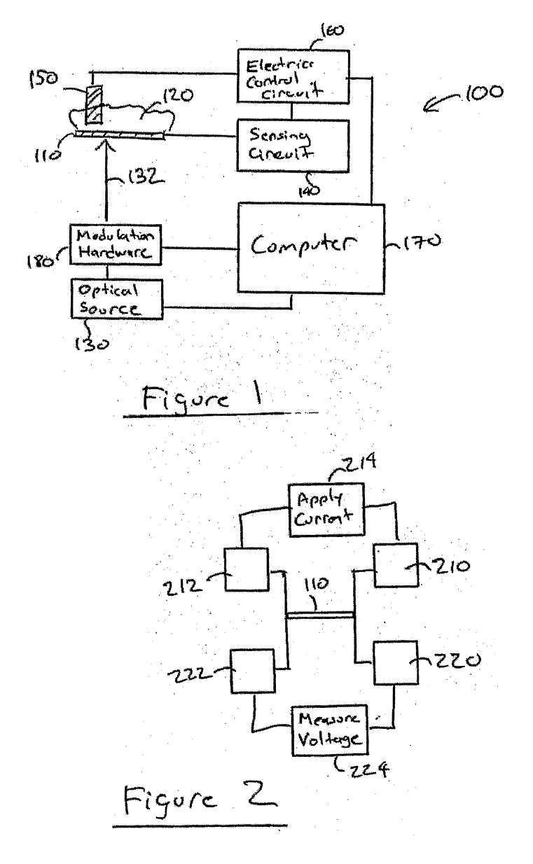

FIG. 1 shows a schematic diagram of one embodiment of an apparatus 100 for electrically detecting plasmon resonances for sensor applications. Referring to FIG. 1, a metallic sensor element 110 is positioned within a dielectric test material 120 containing one or more analytes that may selectively bind to the metallic sensor element. For example, the metallic sensor element 110 can be a gold nanorod and the dielectric test material 120 can be a solution containing analyte molecules that selectively bind to the gold nanorod. The metal-dielectric interface between the metallic sensor element and the dielectric test material define surface plasmon resonances (SPRs). An optical source 130, such as a laser, is configured to direct optical energy 132 to the metallic sensor element 110 to excite the SPRs when selected analyte materials bind to the metallic sensor element. The metallic sensor element 110 is electrically connected to an electric sensing circuit 140 that measures one or more electrical properties of the metallic sensor element 110 in response to the optical excitation.

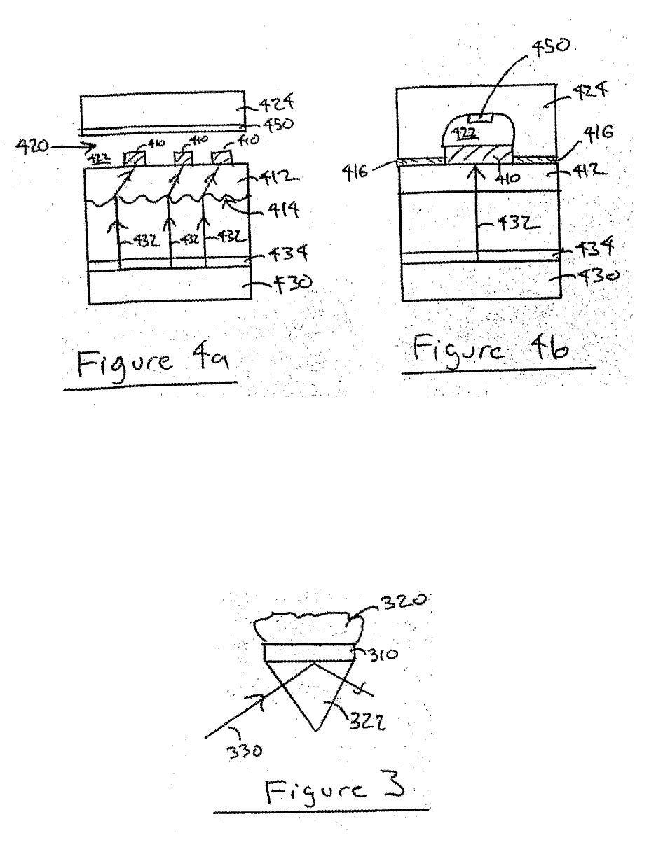

For example, in one embodiment 200 of the electric sensing circuit 140 shown schematically in FIG. 2, the circuit 200 is configured for four-probe conductivity measurements. Specifically, electrodes 210 and 212 are connected to opposite ends of the metallic sensor element 110 and to power supply 214 to apply a current through the metallic sensor element 110. Electrodes 220 and 222 are also connected to the opposite ends of the metallic sensor element 110 and to potentiometer 224 to measure the complementary voltage across sensor element 110 in response to the current applied by power supply 214. Changes in the voltage measured by potentiometer 224 correspond to changes in the resistance (or equivalently, the conductivity) of the metallic sensor element. As explained in greater detail further below, such resistance can change in response to heat generated by the optical excitation of the SPRs. Accordingly, the four-probe conductivity measurements are responsive to the excitation of the SPRs. The electrodes can be made of material the same as, or different from, that of the metallic sensor element. For example, when the metallic sensor element is made of gold, the electrodes may be made of copper.

In other embodiments, for example, the power supply 214 can apply an alternating current through the metallic sensor element 110 at one or more frequencies, and the potentiometer 224 can measure the frequency-dependent complex impedance of the metallic sensor element in response to the optical excitation the metallic sensor element. The frequency-dependent complex impedance is also sensitive to binding events that affect the surface plasmon resonance frequency. Depending on the embodiment, the electric sensing circuit may measure one or both of direct current resistance and alternating current complex impedance at one or more frequencies.

Referring again to FIG. 1, the apparatus 100 further includes a reference electrode 150 in the dielectric test material 120. The reference electrode 150 and electric sensing circuit 140 are both connected to an electric control circuit 160 to apply a variable bias potential between the reference electrode 150 and the metallic sensor element 110 across the dielectric test material 120. For example, when the electric sensor circuit 140 includes the embodiment 200 of FIG. 2, power supply 214 can adjust the average potential applied to the opposite ends of metallic sensor element 110 relative to reference electrode 150. Alternatively, for example, a power supply in electric control circuit 160 can adjust a potential applied to the reference electrode 150 relative to the average potential applied to the opposite ends of the metallic sensor element 110 by electric sensing circuit 140. However produced, the adjustable bias potential can be used to control the binding affinity of one or more selected analytes in the dielectric test material to the metallic sensor element. For example, the bias voltage may be set to cause an oxidation reaction for certain analytes when they are bound to the test sensor, thereby preventing them from binding and/or causing bound species to desorb from the test sensor. In other examples, the bias voltage may set to promote binding, thereby preferentially causing certain analytes to bind to the test sensor.

An electronic controller 170, such as a computer, is coupled to the optical source 130 and the electric control circuit 160 to control the emission of the optical source, to control and adjust the bias potential, and to control, record, and process the measurement by the electric sensing circuit 140.

Furthermore, the apparatus 100 may include optical modulation hardware 180 that selectively varies one or more optical properties of the optical energy produced by optical source 130. The optical modulation hardware is also connected to, and under the control of, electronic controller 170. In some embodiments, the optical modulation hardware can include optical shutters, variable attenuators; or the like, to vary the intensity of the optical energy produced by the optical source. For example, the optical modulation hardware can modulate the intensity of the optical energy at specific frequencies to enable lock-in detection by the electric sensing circuit 140. Specifically, with lock-in detection, the electric sensing circuit identifies changes in the electrical properties of the metallic sensor element 110 that correspond to the specific frequencies used to modulate the intensity of the optical energy. Such lock-in techniques can improve the accuracy of the measurements by the electric sensing circuit by improving signal-to-noise. In additional embodiments, the intensity can be modulated in the optical source itself, for example, by varying an injection current or the like.

In further embodiments, the optical modulation hardware can include polarization modulation components, such as polarizers, retarders, wave plates, and polarization rotators (e.g., those based on electro-optical or acousto-optical effects), which vary the polarization of the optical energy used to excite SPRs in the metallic test sensor. For example, optical energy can be linearly polarized and the polarization modulation components can vary the orientation of that linear polarization. As described in greater detail below, the SPRs can be sensitive to such changes in polarization, especially where the geometric dimensions of the surface of the metallic test sensor have a large aspect ratio.

During operation, the optical source 130 is used to irradiate the metallic sensor element 110 with optical energy in the vicinity of the absorption frequencies of the SPR for the metallic sensor element. For a metallic sensor element made of gold, these absorption frequencies tend to fall in the visible region of the electromagnetic spectrum. If the frequency of the optical energy from the optical source falls within the SPR absorption frequencies, some of the light will be absorbed, thereby heating the metallic sensor element. Such heating will in turn change the electrical properties of the metallic sensor element, for example, by increasing its electrical resistance. Such changes are measured by the electrical sensing circuit.

Now consider immobilizing a selected analyte on the metallic sensor element, where the analyte is a specific binding agent. When the selected analyte species binds to the metallic sensor element, there will be a shift in the SPR absorption frequencies. If the metallic sensor element is irradiated with a wavelength of light at which the surface plasmon absorption changes rapidly with frequency, then a small shift in, and/or attenuation of, the frequency absorption band will cause a readily measurable change in an electrical property of the metallic test sensor, such as electrical resistance. A change in the electrical property measured by the electric test circuit can therefore be indicative of a binding event by the selected analyte to the metallic sensor element. Accordingly, for example, the metallic test sensor can be used to detect the presence or absence of the selected analyte in the dielectric test material. The SPR absorption frequencies for one or more selected analytes may determined in advanced using spectroscopic absorption measurements.

The sensitivity of the test sensor is increased when its dimensions are small enough to produce a meaningful change in its electrical properties in response to the heating caused by the absorption of optical energy by the SPR. For example, in preferred embodiments, the cross-sectional dimensions of the test sensor are less than 1 micron, more preferably, less than 500 nm, for example, on the order of a 100 nm. The small cross sectional area of such a sensor can give it a resistance on the order of a few ohms. Using conventional electrical circuits, this resistance and small changes in it can be measured readily. Moreover, the resistance is large enough that the signal is not highly susceptible to electronic noise. Furthermore, the small surface area of the sensor makes it highly sensitive to a small number of binding events.

Accordingly, in certain embodiments, the metallic sensor element is a nanorod made of a noble metal, such as gold. The dimensions of the nanorod are, for example, a few micrometers in length and on the order of 100 nm in diameter. Electrical connections of the gold nanorod to the electric sensing circuit can be made using, for instance, electron beam lithography or a laser direct writing technique. In other embodiments, for example, the metallic sensor element is nanowire formed on a non-conductive substrate. The nanowire and its associated electrical connection are formed using conventional microlithography techniques. Furthermore, the nanorod or nanowire can be fabricated as a “nanobarcode,” which is a sequence of different materials along its length. For example, the material in the middle of the nanobarcode could be the material on which binding by the selected analyte occurs (e.g., gold), whereas the adjacent materials may materials for which such binding does not occur. Such configurations can be useful when, on the one hand, it is desirable to minimize the length of the active region of the test sensor (i.e., the region where binding by the selected analyte may occur) to make the sensor more sensitive to a small number of binding events, and on the other hand, it is desirable to extend the length of the test sensor to facilitate electrical connections. Techniques for making nanorods, nanowires, and nanobarcodes are known in the art. See, for example: C. R. Martin, “Membrane-Based Synthesis of Nanomaterials,” Chem. Mater. 8, 1739-1746 (1996); S. R. Nicewanier-Pena, R. G. Freeman, B. D. Reiss, L. He, D. J. Pena, I. D. Walton, R. Cromer, C. D. Keating, and M. J. Natan, “Submicrometer Metallic Barcodes,” Science 294, 137-141 (2001); and B. D. Reiss, R. G. Freeman, I. D. Walton, S. M. Norton, P. C. Smith, W. G. Stonas, C. D. Keating, and M. J. Natan, “Electrochemical Synthesis and Optical Readout of Striped Metal Rods with Submicron Features,” J. Electroanal. Chem. 522, 95-103 (2002), all of which are incorporated herein by reference,

In preferred embodiments, the only absorption of the optical energy from the optical source is by SPRs in the test sensor, and not by any bulk material in the test sensor, the electrical connections, or any structure used to support the test sensor. For example, a substrate on which the metallic test sensor is formed is preferably transparent to the optical energy from the optical source. As a result, any heating of the test sensor is directly associated with the absorption of the optical energy by the SPRs.

In certain embodiments, optical excitation of the SPR in the test sensor is facilitated by using an attenuated total internal reflection (ATR) mechanism. In some embodiments, this may be important for phase matching because in bulk materials the propagation constant of the surface plasmon wave is greater than that of the optical wave in the dielectric material. In such cases, the momentum of the incident optical wave can be enhanced to match that of the surface plasmon wave by using ATR. To facilitate ATR, the optical energy can be coupled to the test sensor by using, for example, a prism coupler, a diffraction grating, or an optical waveguide. One such embodiment using a prism coupler is shown in FIG. 3. Optical energy beam 330 from the optical source is directed into a prism coupler 332 at normal incidence and totally internally reflects from the interface between prism coupler a metallic test sensor 310. The optical energy evanescently tunnels through the thickness of the metallic test sensor to excite the surface plasmon wave at the interface between the metallic test sensor 310 and the dielectric test material 320. For more details on the optical excitation of SPRs using ATR and various implementations, see, for example, J. Homola et al, “Surface plasmon resonance sensors: review,” Sensors and Actuators B 54 (1999), 3-15, the contents of which is incorporated herein by reference.

In other embodiments, ATR is not necessary to excite plasmon resonances. For example, when the test sensor is a nanorod, the cylindrical geometry of the test sensor makes it substantially insensitive to the incident angle of the optical energy in the plane perpendicular to the axis of the nanorod. More generally, nanoscale test sensors are small enough that their dimensions and curvature alter bulk wave propagation dynamics.

The electrical detection technique described here is easily extendable to compact, massively parallel arrays of test sensors. This is possible because, for example, the size of each test sensor is preferably small, existing microfabrication techniques can easily provide electrical connections for the electric sensing circuits, and there is no need to monitor and/or angularly resolve the reflection of the optical energy used to excite the SPRs. Moreover, because of its size each test sensor requires a relatively low intensity of light to excite the SPRs making the technique compatible with relatively inexpensive laser diodes. Also, microfluidic channels may be used to expose each test sensor to the dielectric test material, thereby increasing the compactness the sensor array and preserving dielectric test material. Furthermore, in any such sensor array, the electrical connections can be used not only for detection, but also to independently and reprogrammably adjust the bias voltage to each sensor element, thereby selectively setting the binding properties of each sensor.

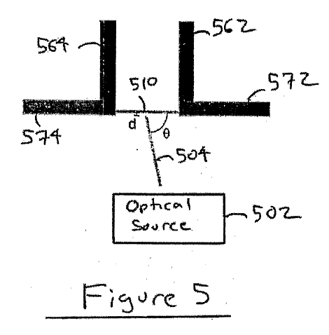

FIGS. 4a and 4b are schematic diagrams showing different cross-sectional views of one embodiment of an SPR sensor array assembly 400 using the electrical detection described above. The assembly includes an array of metallic sensor elements 410, a surface emitting diode array 430, and a microfluidic channel 422 positioned along the sensor elements and formed in a housing 424 to flow dielectric test solution 420. The metallic sensor elements are formed on one side of a substrate 412 transparent to optical energy produced by the diode array. A diffraction grating 414 is formed on the other side of substrate 412 to redirect the optical energy 432 from each diode in diode array 430 to a corresponding sensor element in sensor array 430 so that the optical energy 432 is incident at the interface between substrate 412 and sensor element array 410 at or near an angle that achieves attenuated total internal reflection (ATR) to thereby improve the excitation of SPRs at the interface between sensor element array 410 and dielectric test solution 420. A microlens array 434 is positioned between diode array 430 and diffraction grating 414 to optimize focusing of optical energy 432.

Electrical connections 416 on substrate 412 fan out to connect each sensor element in sensor array 410 to a corresponding electric sensing circuit (not shown), which is in turn connected to an electric control circuit (not shown). Each electric sensing circuit monitors one or more electrical properties of the a corresponding test sensor in the sensor array in response to optical excitation by the diode array when the dielectric test solution is passed over the sensor array. A reference electrode 150 is positioned along channel 422 opposite sensor array 410 and is also connected to the electric control circuit. As described above, the electric control circuit can use the reference electrode and the electrodes associated with the electric sensing circuits to provide an independent and adjustable bias voltage to each sensor element along the microfluidic channel. For ease of illustration, the sensor elements 410 in the FIGS. 4a and 4b are drawn to have a dimensions comparable with, for example, reference electrode 150 and electrical connections 416, in practice, the sensor elements are smaller, e.g., having nanoscale dimensions to enhance their sensitivity to heating caused by the plasmon resonances.

An automated fluid supply system can be used to inject the dielectric test solution into the microfluidic channel. The housing used to form the microfluidic channel can be made of polydimethylsiloxane (PDMS) using existing techniques such as those described in PCT Publication WO 03/006948, the contents of which are incorporated herein by reference.

Also, depending on the desired application for each sensor, the physical dimensions of the sensors may differ from one another. Furthermore, one or more properties of the optical energy used to illuminate each sensor, such as wavelength, intensity, or polarization, may differ from one another.

In additional embodiments, the sensor array assembly may have separate channels for each sensor element. In yet further embodiments, a first layer of microfluidic channels may be oriented with respect to a second or more layers of microfluidic channels to accommodate a two-dimensional array metallic sensor elements, with different dielectric test materials being flowed through the channels of each layer. Such configurations are also described in PCT Publication WO 03/006948 referenced above.

One issue common to SPR sensors relates to how to immobilize various analytes on the metallic test sensors. In one preferred implementation, the test sensors are composed of gold and are protected with thiol-bearing molecules with no specific binding properties. The sensor array is then be exposed to a solution of thiol-bearing binding molecules, including analyte species of interest. The specific sensor to be functionalized is then irradiated with optical energy from the optical source within the plasmon resonance absorption band at a sufficiently high intensity to remove the protecting thiol-bearing molecules. Thereafter, the optical energy is turned off to expose the unprotected sensor to the solution including the analyte species of interest, which in turn bind to the sensor and become immobilized. The optical energy is then turned back on to excite SPRs in the sensor. The electrical properties of the sensor are then monitored to observe shifts in the SPR properties associated with the specific binding of the selected analyte. In other embodiments, amine-bearing molecules could be used instead of, or in addition to, the thiol-bearing molecules.

Also, in other embodiments, the removal of undesired species from a given sensor can be accomplished by adjusting its bias potential relative to the reference electrode, for example, to oxidize the undesired species. Alternatively, the bias potential could be adjusted to promote binding of particular species. See, for example, M. J. Esplandiu et al., “Functionalized Self-Assembled Alkanethiol Monolayers on Au(111) Electrodes: 1. Surface Structure and Electrochemistry,” Langmuir 2001, 17, 828-838, the contents of which are incorporated herein by reference, and which generally describes how a bias voltage affects the formation of self-assembled monolayers (SAMs) on a substrate. The use of the bias potential to control binding can be used instead of, or in addition to, optical excitation (e.g., heating) by the optical source. The electrically detected SPR sensors described above are applicable to a wide variety of analytes, including, for example, small molecules, biomolecules (such as DNA, proteins, antibodies, and the like), and even cells and viruses. Specific materials and techniques for functionalizing the test sensor for a specific analyte are well known in the art. See, for example, J. Homola et al, “Surface plasmon resonance sensors: review,” Sensors and Actuators B 54 (1999), 3-15, and PCT Publication WO 03/006948, both of which were referenced above, and both of which whose contents are incorporated herein by reference.

The electrical detection of plasmon resonances described above is also useful in plasmon resonance waveguide applications. For example, the electrical detection also enables transduction of plasmon resonance signals into electrical signals. This is possible because the decay of a plasmon resonance is necessarily accompanied by heating, which in turn affects electrical properties such as resistance, and which can be detected in nanoscale metal sensor elements as described above.

One embodiment of the transduction of a plasmon resonance signal into an electrical signal is shown schematically in FIG. 5. An optical signal source 502 is configured to produce a plasmon resonance signal at one end of a first metallic element 504, which acts as a waveguide for the plasmon resonance signal. A second metallic element 510 defines a sensor for the plasmon resonance signal and is positioned adjacent the other end of element 504 by a distance “d” and forming angle “θ.” In FIG. 5, for example, the elements form an approximate “T” configuration. The elements themselves can be, for example, gold nanorods or nanowires. Opposite ends of the sensor element 510 are each connected to pairs of electrodes 562, 564, 572, and 574, which form part of an electric sensing circuit (the remainder of which is not shown) for making four-probe conductivity measurement as described in FIG. 2 above.

During operation, source 502 generates a plasmon resonance signal at one end of waveguide element 504. The plasmon resonance signal propagates to the opposite end of element 504, where it can partially couple into sensor element 510. The decay of the plasmon resonance in sensor element 510 produces heat, which is detected with a four-probe conductivity test using the electrodes. As result, the sensor element 510 and the associated electric sensing circuit form a plasmonic receiver for detecting plasmon resonance signals propagated along waveguide element 504. The parameters “d” and “θ” can be set for optimum coupling of the plasmon resonance signal into sensor element 510.

In further embodiments, plasmonic receiver can be used in far more complicated plasmonic circuits than a single waveguiding circuit defined by element 504. For example, the plasmonic circuit can include many nanorods, nanoparticles, and/or other plasmonic elements, including additional receiver elements.

By way of example, several advances in such plasmonic circuitry are described below and the electrical detection method described herein can be exploited with such advances.

Dickson and Lyon demonstrated that light of an appropriate wavelength could be coupled into a gold or silver nanorod in the near field and then would propagate out of the other end, again in the near field (R. M. Dickson and L. A. Lyon, “Unidirectional Plasmon Propagation in Metallic Nanowires” J. Phys. Chem. B 104, 6095-6098 (2000)). These experiments also demonstrated the importance of wavelength-dependent attenuation. Plasmons decay much more quickly with propagation distance in gold than they do in silver, and so the latter metal is able to act as a useful waveguide for shorter wavelengths than is the former metal. Furthermore, in binary nanorods with adjoining segments of gold and silver, this attenuation acts in a sense as an impedance mismatch. While it proved possible to propagate 820-nm light efficiently from the gold portion of a nanorod into the silver portion, the complementary process was quite inefficient. Thus, bimetallic nanorods can act as plasmonic diodes. More recently, Imura et al. have also used NSOM with ultrafast laser pulses to study plasmon dynamics in single nanorods (Kohei Imura, Tetsuhiko Nagahara, and Hiromi Okamoto, “Imaging of Surface Plasmon and Ultrafast Dynamics in Gold Nanorods by Near-Field Microscopy” J. Phys. Chem. B 108, 16344-16347 (2004)).

Closely spaced arrays of individual nanoparticles or nanorods can also be used as plasmonic circuits. For example, when free-electron metal nanostructures are placed in close proximity to one another (where close proximity is determined predominantly by the spatial extent of the plasmon evanescent wave), collective behavior is observed. See, for example, S. A. Maier et al., “Plasmonics—A Route to Nanoscale Optical Devices” Adv. Mater. 13, 1501 (2001); S. A. Maier et al., “Observation of Coupled Plasmon-Polariton Modes in Au Nanoparticle Chain Waveguides of Different Lengths: Estimation of Waveguide Loss” Appl. Phys. Lett. 81, 1714-1716 (2002); S. A. Maier et al., “Observation of Near-Field Coupling in Metal Nanoparticle Chains Using Far-Field Polarization Spectroscopy” Phys. Rev. B 65 (2002); S. A. Maier et al., “Local Detection of Electromagnetic Energy Transport Below the Diffraction Limit in Metal Nanoparticle Plasmon Waveguides” Nature Materials 2, 229-232 (2003); M. Quinten et al., “Electromagnetic Energy Transport via Linear Chains of Silver Nanoparticles” Opt. Lett. 23, 1331-1333 (1998); and K. G. Thomas et al., “Uniaxial Plasmon Coupling Through Longitudinal Self-Assembly of Gold Nanorods” J. Phys. Chem. B 108, 13066-13068 (2004). While most such coupled nanostructures have been studied with far-field optics, more recent near-field studies have demonstrated that nanoparticle chains can serve as plasmon waveguides with relatively low attenuation coefficients. One of the exciting aspects of waveguiding in such particle chains is that it is possible to fabricate the chains with virtually any desired geometry, either via electron-beam lithography or by using an atomic force microscope (AFM) to pattern particles one at a time. For instance, through AFM patterning is has proven possible to create a plasmonic waveguide containing a 60° corner from 30-nm gold nanoparticles. See S. A. Maier et al., “Plasmonics—A Route to Nanoscale Optical Devices” Adv. Mater. 13, 1501 (2001), cited above.

For plasmonic circuitry to have practical applications, it will be desirable to detect plasmonic signals with integrated structures on the same size scale as the plasmonic waveguides themselves. While it may be possible to accomplish this with photodetectors that have been fabricated on the same substrate, detection of only the evanescent wave from the final element of such a device (rather than, for example, any background radiation) may present difficulty. The detection method described herein (and shown in FIG. 5) addresses this difficulty by using a nanoscale sensor to electrically detect the plasmon resonance signal.

### EXAMPLE

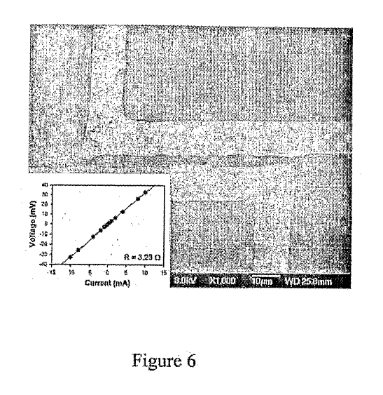

A gold nanorod having a diameter of about 100 nm and a length of a few micrometers was fabricated. The nanorod was fabricated by a standard technique involving electrodeposition of gold in a porous alumina membrane, followed by dissolution of the membrane. The gold nanorod was then connected electrically using laser direct writing of silver from a film containing polyvinylpyrrolidone and silver nitrate that was spin-coated from an ethanol solution. After deposition of the silver the remaining polymer was removed with ethanol, and then the silver was developed with copper using an electroless plating solution containing copper sulfate, sodium hydroxide, Rochelle's salt, and formaldyehyde. A scanning electron micrograph (SEM) of the resulting structure is shown in FIG. 6. A four-probe conductivity test was performed on the gold nanorod through the electrical connections. Specifically, voltage versus current measurements of the gold nanorod were measured, and are shown in the inset of FIG. 6. The voltage versus current results indicated that the gold nanorod had a resistance of approximately 3Ω, which is what one would expect for a gold structure of this size.

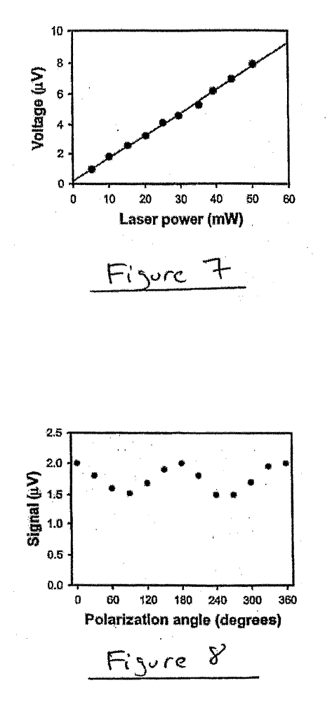

The gold nanorod was then illuminated by an 800-nm laser focused through the microscope objective. The laser beam was modulated using a mechanical chopper, and a lock-in amplifier was referenced to the chopping frequency to reduce noise in the voltage measurement. In the absence of the laser light, the current was set so that the voltage across the nanorod was on the order of 100 μV. When the nanorod was irradiated, there was an easily measurable change in the voltage. The measured change in voltage (ΔV) as a function of laser power is shown in FIG. 7, which shows that the voltage change was on the order of 1% for laser powers as small as a few mW. The change in voltage grew linearly with the applied laser power, and was highly reproducible.

The change in voltage was also measured as a function of the orientation of a linear polarization for the laser beam incident on the gold nanorod, as shown in FIG. 8. This result shows a modulation in the measured voltage change as a function of the orientation of the linear polarization angle.

The cause of the heating of the gold nanorod is that the laser is depositing energy into plasmon resonances. Several lines of evidence support this conclusion. First, 800-nm light cannot drive interband transitions in gold nanostructures. Second, solution-phase spectra of the gold nanorods show that the plasmon resonance band absorbs at 800 nm. Third, it is observed that for a given input power, ultrafast pulses are less efficient at creating a change in resistance than is continuous-wave (CW) radiation. This observation is consistent with significant thermalization of the plasmons occurring during the 100-fs duration of the pulses. In other words, the plasmon absorption band shifts to decrease the absorption on the time scale of the ultrafast pulses, whereas with CW excitation an equilibrium is maintained. The greater efficiency of CW radiation further rules out driving of interband transitions by multiphoton absorption processes.

Finally, the plasmon resonance spectrum of a nanorod is split into two bands that correspond to excitations along the axis of the rod and perpendicular to the axis of the rod, with the former being shifted considerably to the red of the latter. Thus, while interband transitions would not be expected to exhibit any polarization dependence, excitation of the plasmons should exhibit such dependence. The results in FIG. 8 clearly show this. Specifically, there is a modulation in the observed resistance of the nanorod as a function of laser polarization.

As described above, the electrical detection of heating caused by plasmon resonances in a nanorod can be used for both sensor and waveguiding applications.

In further embodiments, the techniques disclosed in commonly owned, U.S. Provisional Patent Application Ser. No. 60/661,204, filed Mar. 11, 2005 and entitled “MICROSTRUCTURES, MICRODEVICES AND RELATED METHODS” by John T. Fourkas and Richard A. Farrer and U.S. Provisional Patent Application Ser. No. 60/660,730, filed Mar. 11, 2005 and entitled “MICROSTRUCTURES, MICRODEVICES AND RELATED METHODS” by John T. Fourkas and Richard A. Farrer, the contents of both applications being incorporated herein by reference in their entirety, may be used to help make any of the structures described herein, such as making electrical connections to, or between, the sensor element(s), making the sensors themselves, and making the plasmonic circuitry.

A number of embodiments of the invention have been described. Nevertheless, it will be understood that various modifications may be made without departing from the spirit and scope of the invention.

What is claimed is:

1. A method comprising:
detecting a plasmon resonance in a material based on a change in at least one electrical property of the material.

2. The method of claim 1, wherein the plasmon resonance is a surface plasmon resonance.

3. The method of claim 1, further comprising optically illuminating the material to produce the plasmon resonance in the material.

4. The method of claim 1, wherein the material is a sensor portion of an electrical circuit, wherein the method further comprises:
exposing the sensor portion to a test material;
optically illuminating the sensor portion when the test material is present, and
monitoring the change in the at least one electrical property of the sensor portion in response to the optical illumination.

5. The method of claim 4, wherein the optical illumination is configured to excite a surface plasmon resonance when a selected analyte in the test material binds to the sensor portion.

6. The method of claim 4, wherein the optical illumination is configured to cause the change in the at least one electrical property of the sensor portion when a selected analyte in the test material binds to the sensor portion.

7. The method of claim 6, wherein the optical illumination causes the change in the at least one electrical property of the sensor portion by heating the sensor portion when the selected analyte in the test material binds to the sensor portion.

8. The method of claim 6, wherein the optical illumination is at least partially absorbed by the sensor portion when the selected analyte in the test material binds to the sensor portion.

9. The method of claim 4, further comprising:
determining information about the test material based on the monitored changed in the at least one electrical property.

10. The method of claim 9, wherein the information about the test material comprises information about a binding affinity of one or more analytes in the test material.

11. The method of claim 9, wherein the information about the test material comprises information about a presence or absence of a selected analyte in the test material

12. The method of claim 4, further comprising, prior to the monitoring, illuminating the sensor portion at an intensity sufficient to remove undesired material bound to the sensor portion and thereby expose the sensor portion to a selected analyte in the test material.

13. The method of claim 4, further comprising, prior to the monitoring, applying a bias voltage to the sensor portion to remove undesired material bound to the sensor portion and thereby expose the sensor portion to a selected analyte in the test material.

14. The method of claim 4, applying a bias voltage to the sensor portion to adjust its affinity for a selected analyte in the test material.

15. The method of claim 4, wherein a polarization of the optical illumination is varied and the change in the at least one electrical property of the sensor portion is monitored in response to the variation in the polarization of the optical illumination.

16. The method of claim 4, wherein a wavelength of the optical illumination is varied and the change in the at least one electrical property of the sensor portion is monitored in response to the variation in the wavelength of the optical illumination.

17. The method of claim 4, wherein an intensity of the optical illumination is varied and the change in the at least one electrical property of the sensor portion is monitored in response to the variation in the intensity of the optical illumination.

18. The method of claim 1, wherein the at least one electrical property comprises electrical resistance.

19. The method of claim 1, wherein the at least one electrical property comprises impedance.

20. The method of claim 19, wherein the at least one electrical property comprises a frequency dependence of the impedance.

21. The method of claim 1, further comprising monitoring the change in the at least one electrical property of the material, wherein the monitoring comprises passing an electrical current through the material.

22. The method of claim 21, wherein the monitoring further comprises measuring a potential difference across the material as the electrical current is being passed through the material.

23. The method of claim 21, wherein the electrical current is a direct current (DC).

24. The method of claim 21, wherein the electrical current is an alternating current (AC).

25. The method of claim 24, wherein the monitoring further comprises varying a frequency of the alternating current.

26. The method of claim 1, wherein the material has a diameter less than about 1 micron.

27. The method of claim 1, wherein the material has a diameter less than about 500 nm.

28. The method of claim 1, wherein the material has a diameter less than about 200 nm.

29. The method of claim 1, wherein the material has a length less than about 10 microns.

30. The method of claim 1, wherein the material comprises a first metal and is connected at opposite ends to a second metal different from the first metal.

31. The method of claim 1, wherein the material comprises a nanorod.

32. The method of claim 1, wherein the material comprises a nanowire.

33. The method of claim 4, wherein the sensor portion of the electrical circuit is supported on a substrate that is substantially transparent to the optical illumination.

34. The method of claim 4, wherein the test material comprises a fluid having thiol- or amine-bearing molecules.

35. The method of claim 4, wherein the optical illumination comprises visible light.

36. The method of claim 4, wherein the test material is exposed to multiple sensor portions, each of which is illuminated when the test material is present.

37. The method of claim 36, wherein a change in an electrical property of each sensor portion is monitored in response to the corresponding optical illumination.

38. The method of claim 36, wherein each sensor portion is configured to be sensitive to a different analyte in the test material in response to its optical illumination.

39. The method of claim 36, wherein physical dimensions of the multiple sensor portions differ.

40. The method of claim 37, wherein properties of the optical illumination for each sensor portion differ.

41. The method of claim 40, wherein the properties of the optical illumination comprise wavelength, intensity, or polarization.

42. The method of claim 36, further comprising independently selecting a bias voltage for each sensor portion.

43. The method of claim 36, wherein the multiple sensor portions are formed as an array on a common substrate.

44. The method of claim 36, wherein the test material is flowed along a microfluidic channel to expose the multiple sensor portions to the test material.

45. The method of claim 1, wherein the material is a part of a receiver for a plasmonic circuit.

46. The method of claim 45, further comprises propagating a plasmon resonance signal along a waveguide and coupling the plasmon resonance signal into the material, wherein the plasmon resonance signal is detected in the material by monitoring the change in at least one electrical property of the material.

47. An apparatus comprising:
a material configured to support a plasmon resonance; and
an electrical sensing circuit coupled to the material, wherein the electrical sensing circuit is configured to monitor a change in at least one electrical property of the material to detect the plasmon resonance.

48. The apparatus of claim 47, wherein the plasmon resonance is a surface plasmon resonance.

49. The apparatus of claim 47, further comprising a source configured to illuminate the material with electromagnetic radiation to produce the plasmon resonance in the material.

50. The apparatus of claim 49, wherein material comprises a sensor portion configured to be exposed to a test material and illuminated by the source, and wherein the electrical sensing circuit is configured to monitor the change in the at least one electrical property in response to the optical illumination when the test material is exposed to the sensor portion.

51. The apparatus of claim 50, wherein the illumination is configured to excite a surface plasmon resonance when a selected analyte in the test material binds to the sensor portion.

52. The apparatus of claim 50, wherein the illumination is configured to cause the change in the at least one electrical property when a selected analyte in the test material binds to the sensor portion.

53. The apparatus of claim 52, wherein the illumination causes the change in the at least one electrical property by heating the sensor portion when the selected analyte in the test material binds to the sensor portion.

54. The apparatus of claim 52, wherein the illumination is at least partially absorbed by the sensor portion when the selected analyte in the test material binds to the sensor portion.

55. The apparatus of claim 50, further comprising an electronic controller configured to determine information about the test material based on the monitored changed in the at least one electrical property.

56. The apparatus of claim 55, wherein the information about the test material comprises information about a binding affinity of one or more analytes in the test material.

57. The apparatus of claim 55, wherein the information about the test material comprises information about a presence or absence of a selected analyte in the test material

58. The apparatus of claim 50, wherein the source is configured to selectively illuminate the sensor portion at an intensity sufficient to remove undesired material bound to the sensor portion and thereby expose the sensor portion to a selected analyte in the test material.

59. The apparatus of claim 50, further comprising a power supply configured to selectively apply a bias voltage to the sensor portion to remove undesired material bound to the sensor portion and thereby expose the sensor portion to a selected analyte in the test material.

60. The apparatus of claim 50 further comprising a power supply configured to selectively apply a bias voltage to the sensor portion to adjust its affinity for a selected analyte in the test material.

61. The apparatus of claim 50, further comprises a means for varying an optical property of the illumination, and wherein the electrical sensing circuit is configured to monitor the change in the at least one electrical property of the sensor portion in response to the variation of the optical property.

62. The apparatus of claim 61, wherein the optical property is at least one of polarization, wavelength, and intensity.

63. The apparatus of claim 47, wherein the at least one electrical property comprises electrical resistance.

64. The apparatus of claim 47, wherein the at least one electrical property comprises impedance.

65. The apparatus of claim 47, wherein the at least one electrical property comprises a frequency dependence of the impedance.

66. The apparatus of claim 47, wherein the electrical sensing circuit is configured to pass an electrical current through the material and measure a potential difference across the material as the electrical current is being passed through the material.

67. The apparatus of claim 66, wherein the electrical current is a direct current (DC).

68. The apparatus of claim 66, wherein the electrical current is an alternating current (AC).

69. The apparatus of claim 68, wherein the electrical sensing circuit is configured to vary a frequency of the alternating current and monitor a change in the potential difference in response to the frequency variation.

70. The apparatus of claim 47, wherein the material has a diameter less than about 1 micron.

71. The apparatus of claim 47, wherein the material has a diameter less than about 500 nm.

72. The apparatus of claim 47, wherein the material has a diameter less than about 200 nm.

73. The apparatus of claim 47, wherein the material has a length less than about 10 microns.

74. The apparatus of claim 47, wherein the material comprises a first metal and is connected at opposite ends to a second metal different from the first metal.

75. The apparatus of claim 74, wherein the material comprises a nanorod.

76. The apparatus of claim 74, wherein the material comprises a nanowire.

77. The apparatus of claim 50, wherein the sensor portion of the electrical sensor circuit is supported on a substrate that is substantially transparent to the illumination.

78. The apparatus of claim 50, wherein the test material comprises a fluid having thiol- or amine-bearing molecules.

79. The apparatus of claim 50, wherein the illumination comprises visible light.

80. The apparatus of claim 50, wherein the material comprises multiple sensor portions configured to be exposed to the test material, wherein the source is configured to illuminate each sensor portion when exposed to the test material.

81. The apparatus of claim 80, further comprising multiple electrical sensing circuits each configured to monitor a change in an electrical property of a corresponding sensor portion in response to the illumination.

82. The apparatus of claim 81, wherein each sensor portion is configured to be sensitive to a different analyte in the test material in response to the illumination.

83. The apparatus of claim 81, wherein physical dimensions of the multiple sensor portions differ.

84. The apparatus of claim 81, wherein properties of the optical illumination for each sensor portion differ.

85. The apparatus of claim 84, wherein the properties of the optical illumination comprise wavelength, intensity, or polarization.

86. The apparatus of claim 81, further comprising a power supply configured to independently apply a bias voltage for each sensor portion.

87. The apparatus of claim 81, wherein the multiple sensor portions are formed as an array on a common substrate.

88. The apparatus of claim 81, further comprising a housing covering the material and defining a microfluidic channel through which the test material is configured to flow to expose the multiple sensor portions to the test material.

89. The apparatus of claim 47, wherein the material is a part of a receiver for a plasmonic circuit.

90. The apparatus of claim 89, further comprising a plasmonic waveguide configured to propagate a plasmon resonance signal and positioned relative to the receiver to couple the plasmon resonance signal into the material, and wherein the electrical sensing circuit is configured to detect plasmon resonance signal by monitoring the change in at least one electrical property of the material.
